(19) United States
(12) Patent Application Publication
(10) Pub. No.: US 2025/0204205 A1
(43) Pub. Date: Jun. 19, 2025

(54) DISPLAY PANEL AND DISPALY DEVICE

(71) Applicant: Shenzhen China Star Optoelectronics Semiconductor Display Technology Co., Ltd., Shenzhen (CN)

(72) Inventor: Zhiyuan YIN, Shenzhen (CN)

(73) Assignee: Shenzhen China Star Optoelectronics Semiconductor Display Technology Co., Ltd., Shenzhen (CN)

(21) Appl. No.: 19/073,043

(22) Filed: Mar. 7, 2025

(30) Foreign Application Priority Data
Mar. 7, 2023 (CN) 202410265913.X

(51) Int. Cl. H10K 59/80; H10K 59/35

(52) U.S. Cl. CPC H10K 59/80521; H10K 59/353; H10K 59/80523; H10K 59/80524

(57) ABSTRACT

A display panel and a display device. The display panel includes a first display area and a second display area, a light transmittance of the first display area being greater than that of the second display area. The first display area is provided with first light-emitting devices and second light-emitting devices, which are arranged adjacent to each other. By making the light transmittance of the first cathode of the first light-emitting devices less than that of the second cathode of the second light-emitting devices, the difference in reflectivity between adjacent light-emitting devices is increased. This reduces the intensity concentration in the direction of diffraction of the first display area and disrupts the array diffraction between adjacent first and second light-emitting devices.

### CROSS-REFERENCE TO RELATED APPLICATION

This application claims priority to and the benefit of Chinese Patent Application No. 202410265913.X, filed on Mar. 7, 2024, the disclosure of which is incorporated herein by reference in its entirety.

### TECHNICAL FIELD

The present disclosure relates to the field of display technologies, and in particular, to a display panel and a display device.

### BACKGROUND

Currently, under-display camera technology remains a promising direction for the development of organic light-emitting diode (OLED) display technology, and is considered the ultimate form of display technology for the next phase. In top-emission OLED display panels, the main factors that affect light transmittance are metal electrodes (i.e., cathodes and anodes) and metal wiring. To allow more light to pass through the under-display camera area and ensure camera performance, the mainstream design currently reduces the number of light-emitting devices and metal wiring in the under-display camera area or replaces the metal wiring in the under-display camera area with transparent conductive materials and places the driving circuitry outside the under-display camera area to increase the light transmittance of the under-display camera area.

However, existing under-display camera technology retains all or most of the light-emitting devices in the under-display camera area. The metal electrodes of these devices form a metal electrode array, which leads to a more noticeable diffraction phenomenon in the under-display camera area, severely affecting the camera performance. Moreover, the light reflected by the metal electrodes may cause a noticeable color separation phenomenon, affecting the display effect of the under-display camera area.

### SUMMARY

An embodiment of the present disclosure provides a display panel including:
a first display area; and
a second display area disposed around a periphery of the first display area, a light transmittance of the first display area being greater than a light transmittance of the second display area,
where the first display area is provided with a plurality of first light-emitting devices and a plurality of second light-emitting devices, which are arranged adjacent to each other, each of the first light-emitting devices has a first cathode, and each of the second light-emitting devices has a second cathode, a light transmittance of the first cathode being less than a light transmittance of the second cathode.

An embodiment of the present disclosure further provides a display device including a display panel, the display panel including:
a first display area; and
a second display area disposed around a periphery of the first display area, a light transmittance of the first display area being greater than a light transmittance of the second display area,
where the first display area is provided with a plurality of first light-emitting devices and a plurality of second light-emitting devices, which are arranged adjacent to each other, each of the first light-emitting devices has a first cathode, and each of the second light-emitting devices has a second cathode, a light transmittance of the first cathode being less than a light transmittance of the second cathode.

### BRIEF DESCRIPTION OF THE DRAWINGS

To more clearly illustrate the technical solutions in the embodiments of the present disclosure, the accompanying drawings to be used in the description of the embodiments will be briefly introduced below. It is obvious that the accompanying drawings described below are merely some embodiments of the present disclosure. For a person of ordinary skill in the art, other drawings can be obtained based on these drawings without the need for creative effort.

FIG. 1 is a schematic diagram of a structure of a display device provided in an embodiment of the present disclosure;

FIG. 2 is a schematic planar view of a display panel provided in an embodiment of the present disclosure;

FIG. 3 is a schematic diagram of a stack of layers of a first display area provided in an embodiment of the present disclosure;

FIG. 4 is a schematic diagram of a distribution of light-emitting devices in a first display area provided in an embodiment of the present disclosure.

FIG. 5 is a schematic diagram of a distribution of light-emitting devices in a second display area provided in an embodiment of the present disclosure.

### DETAILED DESCRIPTION

The descriptions of following embodiment are provided with reference to the accompanying drawings to illustrate specific embodiments by which the present disclosure may be implemented. The directional terms mentioned in the present disclosure, such as “up,” “down,” “front,” “back,” “left,” “right,” “inside,” “outside,” “side,” etc., are merely directions with reference to the accompanying drawings. Therefore, the directional terms used are for the purpose of explaining and understanding the present disclosure, and are not intended to limit the present disclosure. In the drawings, units with similar structures are indicated with the same reference numerals.

Below, further details of the present disclosure are provided in conjunction with the accompanying drawings and specific embodiments.

An embodiment of the present disclosure provides a display panel and a display device that not only reduce the diffraction effect in a first display area, enhancing the image quality, but also improve the color separation phenomenon in the first display area, enhancing the display effect of the first display area.

The display device provided in an embodiment of the present disclosure may be a mobile display device such as a smartphone, a smartwatch, a tablet, or a laptop, or it may be a stationary display device such as a desktop computer or a television.

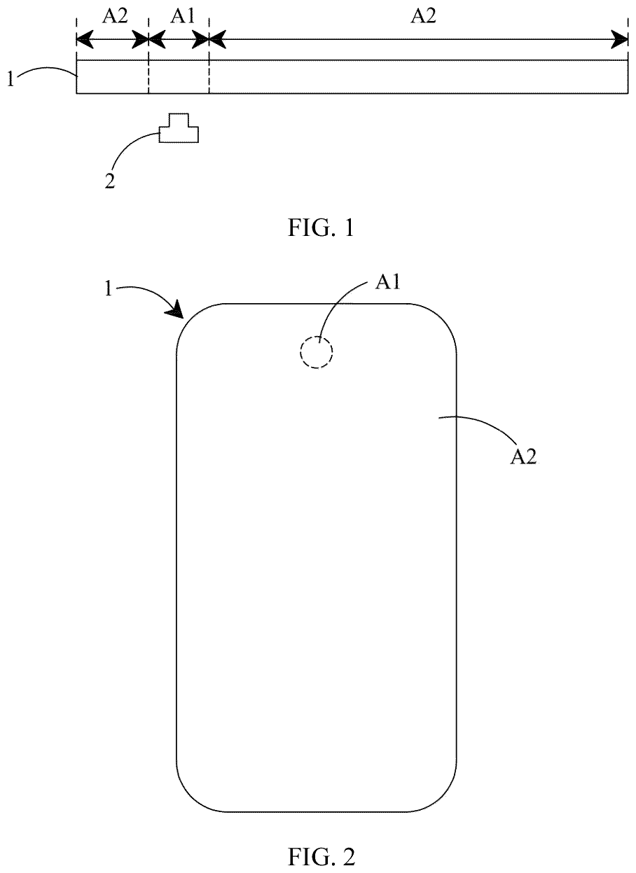

Referring to FIG. 1 and FIG. 2, where FIG. 1 is a schematic diagram of a structure of a display device provided in an embodiment of the present disclosure, and FIG. 2 is a schematic planar view of a display panel provided in an embodiment of the present disclosure. The display device includes a display panel 1 and a camera module 2. The display panel includes a first display area A1 and a second display area A2 disposed around a periphery of the first display area A1. A light transmittance of the first display area A1 is greater than a light transmittance of the second display area A2. The camera module 2 is positioned corresponding to the first display area A1.

The first display area A1 may be considered as an under-display camera area, with the camera module 2 located on a back side of the display panel 1. An orthographical projection of the camera module 2 on the display panel 1 overlaps with the first display area A1. The back side of the display panel 1 is a side opposite to a light-emitting side of the display panel 1. The camera module 2 may capture ambient light through the first display area A1 to achieve functionalities of an under-display camera.

In an embodiment, a shape of the first display area A1 is circular. The second display area is arranged around the first display area A1, forming a fully enclosing structure around the first display area A1. In some other embodiments, the shape of the first display area A1 may also be elliptical or rectangular, among others.

In an embodiment, by reducing the number of light-emitting devices in the first display area A1 and lowering its resolution to be less than that of the second display area A2, a higher light transmittance in the first display area A1 than in the second display area A2 is achieved.

In an embodiment, the resolution of the first display area A1 is equal to the resolution of the second display area A2. The light transmittance of the first display area A1 is made greater than the light transmittance of the second display area A2 by replacing a material of signal wirings in the first display area A1 from metal to a transparent conductive material, or by moving drive circuits within the first display area A1 to the second display area A2, thereby increasing an area of the light-transmitting region in the first display area A1.

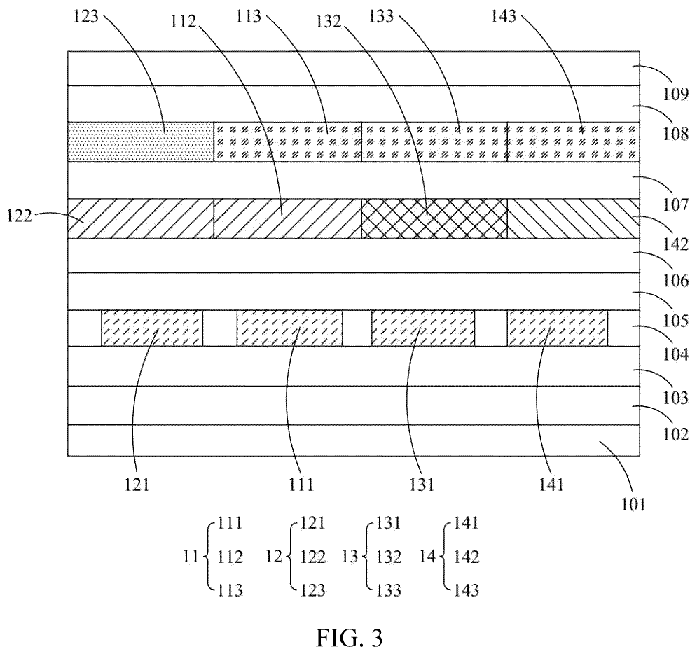

Referring to FIG. 3, FIG. 3 is a schematic diagram of a stack of layers of a first display area A1 provided in an embodiment of the present disclosure. The display panel 1 includes a substrate 101 as well as a driving circuit layer 102, a planarization layer 103, a pixel definition layer 104, a light-emitting device layer, an encapsulation layer 108, and a protective layer 109 stacked on the substrate 101.

The substrate 101 may be a flexible substrate or a rigid substrate. A material of the flexible substrate may include, but is not limited to, polyimide, while the rigid substrate is a glass substrate. The protective layer 109 is a glass cover plate.

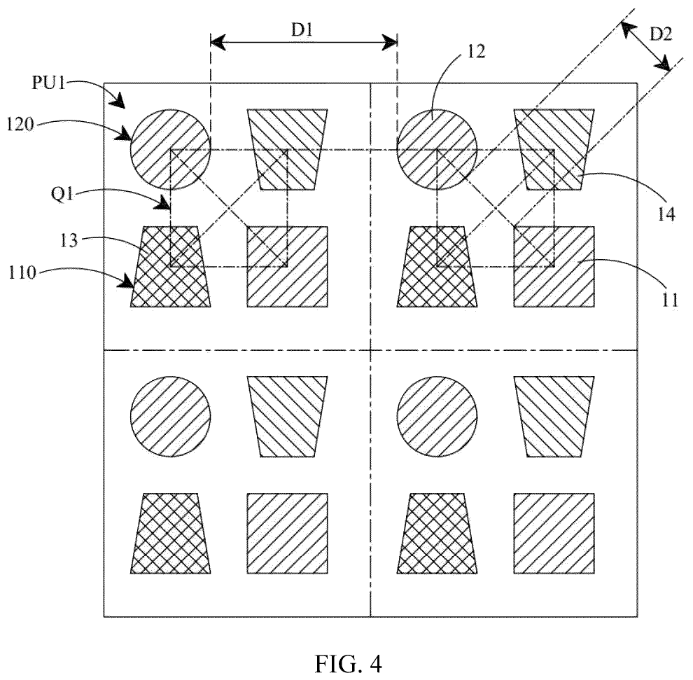

Referring to FIG. 3 and FIG. 4, FIG. 4 is a schematic diagram of a distribution of light-emitting devices in a first display area provided in an embodiment of the present disclosure. The first display area A1 is provided with a plurality of first light-emitting devices 11 and a plurality of second light-emitting devices 12, which are arranged adjacent to each other.

The first light-emitting devices 11 and the second light-emitting devices 12 are both organic light-emitting diodes. Each of the first light-emitting devices 11 has a first anode 111, a first light-emitting layer 112, and a first cathode 113 in a stack configuration. Each of the second light-emitting devices 12 has a second anode 121, a second light-emitting layer 122, and a second cathode 123 in a stack configuration.

In an embodiment of the present disclosure, a light transmittance of the first cathode 113 is less than a light transmittance of the second cathode 123. Due to a negative correlation between the light transmittance and reflectivity of the first cathode 113 and the second cathode 123, i.e., the higher the light transmittance, the lower the reflectivity, the reflectivity of the first cathode 113 may be made greater than that of the second cathode 123 by making the light transmittance of the first cathode 113 less than that of the second cathode 123. This may increase the difference in reflectivity between adjacent first and second light-emitting devices 11 and 12, thereby reducing the intensity concentration in a direction of diffraction of the first display area A1, disrupting an array diffraction between the adjacent first and second light-emitting devices 11 and 12. Therefore, not only can the diffraction effect of the first display area A1 be reduced, enhancing the image quality, but also the color separation phenomenon of the first display area A1 can be improved, enhancing the display effect of the first display area.

In some embodiments, a material of the first cathode 113 is metal, and a material of the second cathode 123 is transparent conductive oxide. By replacing the material of the second cathode 123 of the second light-emitting devices 12 with the transparent conductive oxide that has a higher light transmittance, the difference in reflectivity between adjacent first and second light-emitting devices 11 and 12 may be increased, thereby reducing the array diffraction in the first display area A1.

In an embodiment, the material of the first cathode 113 is silver, and the material of the second cathode 123 is indium tin oxide (ITO).

In some embodiments, a light-emitting color of the first light-emitting devices 11 is the same as that of the second light-emitting devices 12.

In an embodiment, each of the first light-emitting devices 11 is a green light-emitting device, and each of the second light-emitting devices 12 is also a green light-emitting device. The difference between the first light-emitting devices and the second light-emitting devices 12 lies only in the material of the cathode. Due to the highest luminous efficiency of green light-emitting devices, the reflectivity of the cathodes of a portion of the green light-emitting devices in the first display area A1 is reduced by replacing materials of the cathodes of the portion of the green light-emitting devices in the first display area A1 with transparent conductive oxide. This reduces the reflective microcavity of some green light-emitting devices and increases the difference in reflectivity between adjacent green light-emitting devices in the first display area A1, thereby reducing the array diffraction in the first display area A1.

Further, as shown in FIG. 4, a minimum distance between one of the second light-emitting devices 12 and a nearest another one of the second light-emitting devices 12 is denoted as a first distance D1, the first distance D1 being measured as a distance between centers of the two second light-emitting devices 12 along a line that connects these centers. A minimum distance between one of the second light-emitting devices 12 and a nearest one of the first light-emitting devices 11 is denoted as a second distance D2, the second distance D2 being measured as a distance between centers of the second light-emitting device 12 and its nearest first light-emitting device 11 along a line that connects these centers. The first distance D1 is greater than the second distances D2, meaning that in the first display area A1, the distance between adjacent identical second light-emitting devices 12 is greater than the distance between adjacent first and second light-emitting devices 11 and 12. This not only increases the difference in reflectivity between adjacent green light-emitting devices by utilizing the second light-emitting devices 12, reducing the array diffraction, but also ensures that the display effect of the display panel is not affected.

Further, the first display area A1 further includes a plurality of third light-emitting devices 13 and a plurality of fourth light-emitting devices 14, with the light-emitting colors of the third light-emitting devices 13, the fourth light-emitting devices 14, and the first light-emitting devices 11 being different from each other.

The third and fourth light-emitting devices 14 are both organic light-emitting diodes. Each of the third light-emitting devices 13 has a third anode 131, a third light-emitting layer 132, and a third cathode 133 in a stack configuration. Each of the fourth light-emitting devices 14 has a fourth anode 141, a fourth light-emitting layer 142, and a fourth cathode 143 in a stack configuration. The first light-emitting device 11 shares a hole injection layer 105, a hole transport layer 106, an electron transport layer, and an electron injection layer 107 with the second, third, and fourth light-emitting devices 12, 13, 14, and the light-emitting devices in the second display area A2.

In an embodiment of the present disclosure, a light transmittance of the third cathode 133 is less than the light transmittance of the second cathode 123. A light transmittance of the fourth cathode 143 is less than the light transmittance of the second cathode 123.

It should be noted that the cathode can only transmit a portion of the light emitted by the light-emitting layer; the rest of the light is reflected by the cathode. By making the light transmittance of the second cathode 123 greater than that of the first, third, and fourth cathodes 113, 133, 143, the reflectivity of the second cathode 123 is less than that of the first, third, and fourth cathodes 113, 133, 143. This increases the difference in reflectivity between the second light-emitting devices 12 and any adjacent ones of the first light-emitting devices 11, the third light-emitting devices 13, and the fourth light-emitting devices 14, thereby further reducing the intensity of light convergence in the direction of diffraction of the first display area A1. Because the material of the second cathode 123 is transparent conductive oxide, which has a higher light transmittance compared to metallic materials, there will be no slits or holes that are formed between a second cathode 123 and any adjacent first cathode 113, third cathode 133, or fourth cathode 143 and whose peripheries are opaque to light. Therefore, light will not diffract between the second cathode 123 and the adjacent first cathode 113, third cathode 133, or fourth cathode 143, preventing array diffraction between the second light-emitting devices 12 and the adjacent first light-emitting devices 11, third light-emitting devices 13, or fourth light-emitting devices 14 within the first display area A1. This not only reduces the diffraction effect in the first display area A1, improving image quality, but also improves the color separation phenomenon in the first display area A1, enhancing the display effect in the first display area.

In an embodiment, a material of the third cathode 133 is metal, and a material of the fourth cathode 143 is metal. The first cathode 113 is made of the same material as the third and fourth cathode 133 and 143, and they are integrated, meaning that the first light-emitting devices 11 share same cathodes with the third and fourth light-emitting devices 13 and 14.

As shown in FIG. 3, the second cathode 123 is provided in the same layer as the first cathode 113. Both the first cathode 113 and the second cathode 123 are disposed on a surface of the electron transport layer and the electron injection layer 107 away from the substrate 101. The order of fabrication of the first and second cathode 113 and 123 is not limited. A patterned first cathode 113 may be formed first, without overlapping with the second light-emitting layer 122 in a thickness direction, and then a patterned second cathode 123 may be formed above the second light-emitting layer 122. Alternatively, the patterned second cathode 123 may be formed first, followed by the first cathode 113.

In an embodiment, the first light-emitting devices 11 and the second light-emitting devices 12 are green light-emitting devices, the third light-emitting devices 13 are red light-emitting devices, and the fourth light-emitting devices 14 are blue light-emitting devices.

As shown in FIG. 4, the first display area A1 is provided with a plurality of first pixel units PU1 arranged in a repeating pattern. Each of the first pixel unit PU1 includes a first light-emitting device 11, a second light-emitting device 12, a third light-emitting device 13, and a fourth light-emitting device 14.

As shown in FIG. 4, in the first pixel unit PU1, a center of the first light-emitting device 11, a center of the second light-emitting device 12, a center of the third light-emitting device 13, and a center of the fourth light-emitting device 14 are respectively located at the four vertices of a virtual quadrilateral Q1. The center of the first light-emitting device 11 and the center of the second light-emitting device 12 are on one diagonal of the virtual quadrilateral Q1, while the center of the third light-emitting device 13 and the center of the fourth light-emitting device 14 are on another diagonal of the virtual quadrilateral Q1. By arranging the light-emitting devices in the first display area A1 according to the sub-pixel rendering (SPR) algorithm and utilizing the viewing direction compensation (VDC) algorithm when displaying images in the first display area A1, it is ensured that the distance between adjacent light-emitting devices with the same cathode material is greater than the distance between adjacent light-emitting devices with different cathode materials. This may further reduce the intensity concentration in the direction of diffraction, and to the greatest extent, disrupt the array extension between the light-emitting devices.

In an embodiment, the number of the first light-emitting devices 11 is the same as the number of the second light-emitting devices 12 in the first display area A1. With this ratio, by replacing the cathode material of a portion of the blue light-emitting devices (i.e., the fourth light-emitting device 14) with transparent conductive oxide, the diffraction effect of the first display area A1 may be reduced, image quality may be enhanced, and the color separation phenomenon in the first display area A1 may be improved. Moreover, due to the higher luminous efficiency of green light-emitting devices with metal cathodes compared to that of green light-emitting devices with transparent metal oxide cathodes, this ratio also ensures that there are an adequate number of green light-emitting devices with metal cathodes (i.e., the first light-emitting devices 11) in the first display area A1, preventing the luminous efficiency of the first display area A1 from being too low due to a lack of the first light-emitting devices 11, which could affect the display effect of the first display area A1.

In some embodiments, the second light-emitting devices are of circular or elliptical shapes, and the shapes of the first, third, and fourth light-emitting devices are different from the shapes of the second light-emitting devices.

As shown in FIG. 4, the display panel includes a plurality of first pixel apertures 110 and a plurality of second pixel apertures 120, which may be formed in the pixel definition layer (not shown in the figure) of the display panel. The first, third, and fourth light-emitting devices 11, 13, and 14 are respectively disposed within their corresponding first pixel apertures 110, and the second light-emitting devices 12 are disposed within the second pixel apertures 120. The first and second pixel apertures 110 and 120 may define shapes of respective light-emitting devices.

In an embodiment, a cross-sectional shape of the second pixel apertures 120, taken perpendicular to a depth direction, is circular. A cross-sectional shape of the first pixel apertures 110, taken perpendicular to the depth direction, is different from that of the second pixel apertures 120. Herein, the cross-sectional shape, taken perpendicular to depth direction, of the first pixel apertures 110 corresponding to the first light-emitting devices 11 is rectangular. The cross-sectional shape, taken perpendicular to depth direction, of the first pixel apertures 110 corresponding to the third light-emitting devices 13 is trapezoidal. The cross-sectional shape, taken perpendicular to depth direction, of the first pixel apertures 110 corresponding to the fourth light-emitting devices 14 is inverted trapezoidal. By setting the cross-sectional shape of the second pixel apertures 120 corresponding to the second light-emitting devices 12 to be circular, the spacing between edges of the second light-emitting devices 12 and edges of the surrounding adjacent light-emitting devices may be increased. This reduces the diffraction intensity in all directions for the second light-emitting devices 12.

In some other embodiments, the cross-sectional shape, taken perpendicular to the depth direction, of the second pixel apertures 120 may also be elliptical, which may as well reduce the diffraction intensity in all directions. In practical applications, the cross-sectional shape, taken perpendicular to the depth direction, of the first pixel apertures 110 is not limited to the rectangular shape mentioned in the above embodiments; it may also be triangular, diamond-shaped, pentagonal, or other regular or irregular shapes.

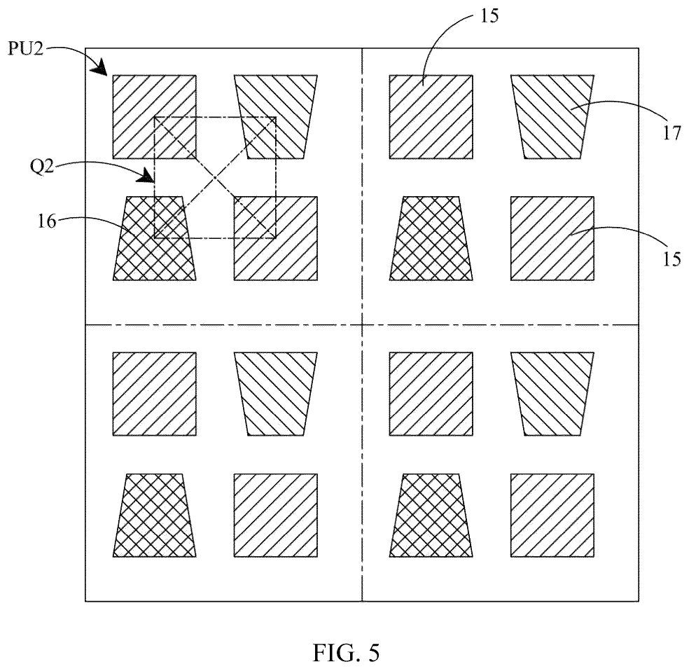

As shown in FIG. 5, FIG. 5 is a schematic diagram of a distribution of light-emitting devices in a second display area provided in an embodiment of the present application. The second display area A2 includes a plurality of fifth light-emitting devices 15, a plurality of sixth light-emitting devices 16, and a plurality of seventh light-emitting devices 17. The fifth, sixth, and seventh light-emitting devices 15, 16, and 17 are all organic light-emitting devices, and their cathodes are all made of metal. The fifth light-emitting devices 15 are green light-emitting devices, the sixth light-emitting devices 16 are red light-emitting devices, and the seventh light-emitting devices 17 are blue light-emitting devices. The layer structure of the fifth, sixth, and seventh light-emitting devices 15, 16, and 17 may refer to the layer structure of the first, third, and fourth light-emitting devices 11, 13, and 14 shown in FIG. 3, and is not further described here.

In some embodiments, as shown in FIG. 5, the second display area A2 includes a plurality of second pixel units PU2, each second pixel unit PU2 including two fifth light-emitting devices 15, a sixth light-emitting device 16, and a seventh light-emitting device 17. The centers of the two fifth light-emitting devices 15, the one sixth light-emitting device 16, and the one seventh light-emitting device 17 are respectively located at the four vertices of a second virtual quadrilateral Q2. The centers of the two fifth light emitting devices 15 are on one diagonal of the second virtual quadrilateral Q2, and the centers of the sixth and seventh light emitting devices 16 and 17 are on another diagonal of the second virtual quadrilateral Q2. The light-emitting devices in the second display area A2, like those in the first display area A1, are arranged utilizing the sub-pixel rendering (SPR) algorithm.

Based on the display panels provided in the above embodiments of the present disclosure, embodiments of the present application also provide a display device. The display device includes the display panel provided in any of the above embodiments and is not limited to, but may include, display devices such as a smartphone, a smartwatch, a desktop computer, a laptop, and a television, among others.

Beneficial effects of the present embodiment are as follows. The embodiments of the present disclosure provide a display panel including a first display area and a second display area. The light transmittance of the first display area is greater than that of the second display area. The first display area is provided with a plurality of first light-emitting devices and a plurality of second light-emitting devices, which are arranged adjacent to each other. By making the light transmittance of the first cathode of the first light-emitting devices less than that of the second cathode of the second light-emitting devices, the difference in reflectivity between adjacent light-emitting devices is increased. This reduces the intensity concentration in the direction of diffraction of the first display area and disrupts the array diffraction between adjacent first and second light-emitting devices. Consequently, this not only reduces the diffraction effect in the first display area, enhancing the image quality, but also improves the color separation phenomenon in the first display area, enhancing the display effect of the first display area.

In summary, although the present disclosure is disclosed with preferred embodiments as described above, these preferred embodiments are not intended to limit the scope of the present disclosure. A person of ordinary skill in the art, without departing from the spirit and scope of the present disclosure, may make various modifications and refinements. Therefore, the protective scope of the present disclosure is based on the scope defined by the appended claims.

What is claimed is:

1. A display panel comprising:
a first display area; and
a second display area disposed around a periphery of the first display area, a light transmittance of the first display area being greater than a light transmittance of the second display area,
wherein the first display area is provided with a plurality of first light-emitting devices and a plurality of second light-emitting devices, which are arranged adjacent to each other, each of the first light-emitting devices has a first cathode, and each of the second light-emitting devices has a second cathode, a light transmittance of the first cathode being less than a light transmittance of the second cathode.

2. The display panel of claim 1, wherein a material of the first cathode is metal, and a material of the second cathode is transparent conductive oxide.

3. The display panel of claim 1, wherein a light-emitting color of the first light-emitting devices is the same as a light-emitting color of the second light-emitting devices.

4. The display panel of claim 3, wherein a minimum distance between one of the second light-emitting devices and a nearest another one of the second light-emitting devices is a first distance, and a minimum distance between one of the second light-emitting devices and a nearest one of the first light-emitting devices is a second distance, the first distance being greater than the second distance.

5. The display panel of claim 3, wherein the first display area further includes a plurality of third light-emitting devices and a plurality of fourth light-emitting devices, with light-emitting colors of the third, fourth, and first light-emitting devices being different from each other,
wherein each of the third light-emitting devices has a third cathode, each of the fourth light-emitting devices has a fourth cathode, a light transmittance of the third cathode being less than the light transmittance of the second cathode, and a light transmittance of the fourth cathode being less than the light transmittance of the second cathode.

6. The display panel of claim 5, wherein materials of the first, third, and fourth cathodes are all metal, and a material of the second cathode is transparent conductive oxide.

7. The display panel of claim 5, wherein the first light-emitting devices are green light-emitting devices, the second light-emitting devices are green light-emitting devices, the third light-emitting devices are red light-emitting devices, and the fourth light-emitting devices are blue light-emitting devices.

8. The display panel of claim 5, wherein a center of one of the first light-emitting devices, a center of one of the second light-emitting devices, a center of one of the third light-emitting devices and a center of one of the fourth light-emitting devices are respectively located at four vertices of a virtual quadrilateral, the centers of the first and second light-emitting devices being on one diagonal of the virtual quadrilateral, while the centers of the third and fourth light-emitting devices being on another diagonal of the virtual quadrilateral.

9. The display panel of claim 5, wherein the display panel comprises a plurality of first pixel apertures and a plurality of second pixel apertures, the first, third and fourth light-emitting devices are respectively disposed within their corresponding first pixel apertures, and the second light-emitting devices are disposed within the second pixel apertures,
wherein a cross-sectional shape of the second pixel apertures, taken perpendicular to a depth direction, is circular or elliptical, the cross-sectional shape, taken perpendicular to the depth direction, of the second pixel apertures being different from a cross-sectional shape, taken perpendicular to the depth direction, of the first pixel apertures.

10. A display device comprising a display panel, the display panel comprising:
a first display area; and
a second display area disposed around a periphery of the first display area, a light transmittance of the first display area being greater than a light transmittance of the second display area,
wherein the first display area is provided with a plurality of first light-emitting devices and a plurality of second light-emitting devices, which are arranged adjacent to each other, each of the first light-emitting devices has a first cathode, and each of the second light-emitting devices has a second cathode, a light transmittance of the first cathode being less than a light transmittance of the second cathode.

11. The display device of claim 10, wherein a material of the first cathode is metal, and a material of the second cathode is transparent conductive oxide.

12. The display device of claim 10, wherein a light-emitting color of the first light-emitting devices is the same as a light-emitting color of the second light-emitting devices.

13. The display device of claim 12, wherein a minimum distance between one of the second light-emitting devices and a nearest another one of the second light-emitting devices is a first distance, and a minimum distance between one of the second light-emitting devices and a nearest one of the first light-emitting devices is a second distance, the first distance being greater than the second distance.

14. The display device of claim 12, wherein the first display area further includes a plurality of third light-emitting devices and a plurality of fourth light-emitting devices, with light-emitting colors of the third, fourth, and first light-emitting devices being different from each other,
wherein each of the third light-emitting devices has a third cathode, each of the fourth light-emitting devices has a fourth cathode, a light transmittance of the third cathode being less than the light transmittance of the second cathode, and a light transmittance of the fourth cathode being less than the light transmittance of the second cathode.

15. The display device of claim 14, wherein materials of the first, third, and fourth cathodes are all metal, and a material of the second cathode is transparent conductive oxide.

16. The display device of claim 14, wherein the first light-emitting devices are green light-emitting devices, the second light-emitting devices are green light-emitting devices, the third light-emitting devices are red light-emitting devices, and the fourth light-emitting devices are blue light-emitting devices.

17. The display device of claim 14, wherein a center of one of the first light-emitting devices, a center of one of the second light-emitting devices, a center of one of the third light-emitting devices and a center of one of the fourth light-emitting devices are respectively located at four vertices of a virtual quadrilateral, the centers of the first and second light-emitting devices being on one diagonal of the virtual quadrilateral, while the centers of the third and fourth light-emitting devices being on another diagonal of the virtual quadrilateral.

18. The display device of claim 14, wherein the display panel comprises a plurality of first pixel apertures and a plurality of second pixel apertures, the first, third and fourth light-emitting devices are respectively disposed within their corresponding first pixel apertures, and the second light-emitting devices are disposed within the second pixel apertures,
wherein a cross-sectional shape of the second pixel apertures, taken perpendicular to a depth direction, is circular or elliptical, the cross-sectional shape, taken perpendicular to the depth direction, of the second pixel apertures being different from a cross-sectional shape, taken perpendicular to the depth direction, of the first pixel apertures.

19. The display device of claim 10, wherein the second display area is provided with a plurality of fifth light emitting devices, a plurality of sixth light emitting devices, and a plurality of seventh light emitting devices,
wherein, centers of two of the fifth light emitting devices, a center of one of the sixth light emitting devices, and a center of one of the seventh light emitting devices are respectively located at four vertices of a second virtual quadrilateral.

20. The display device of claim 19, wherein the centers of the two fifth light emitting devices are on one diagonal of the second virtual quadrilateral, and the center of the sixth and seventh light emitting devices are on another diagonal of the second virtual quadrilateral.
